(19) United States
(12) Patent Application Publication
(10) Pub. No.: US 2010/0052471 A1
(43) Pub. Date: Mar. 4, 2010

(54) High frequency surface acoustic wave device

(75) Inventors: Wen-Ching Shih, Taipei (TW); Mao-Jin Wang, Taipei (TW)

Correspondence Address: BACON & THOMAS, PLLC, 625 SLATERS LANE, FOURTH FLOOR, ALEXANDRIA, VA, 22314-1176, US

(73) Assignees: Tatung Company, Taipei (TW); Tatung University, Taipei (TW)

(21) Appl. No.: 12/289,121

(22) Filed: Oct. 21, 2008

(30) Foreign Application Priority Data
Aug. 29, 2008 (TW) 097133049

(51) Int. Cl. H01L 41/083

(52) U.S. Cl. 310/313 B

(57) ABSTRACT

A high frequency surface acoustic wave device is disclosed. The disclosed high frequency surface acoustic wave device can modulate its central frequency easily, by changing the thickness of its nanocrystalline diamond layer. The disclosed high frequency surface acoustic wave device comprises: a silicon substrate; a nanocrystalline diamond layer located above the silicon substrate; a piezoelectric layer formed on the surface of the nanocrystalline diamond layer; an input transformation unit; and an output transformation unit, wherein the input transformation unit and the output transformation unit are formed in pairs on the surface or beneath of the piezoelectric layer. Besides, the thickness of the nanocrystalline diamond layer is preferably between 0.5 μm and 20 μm. The piezoelectric layer is preferably made of ZnO, AlN, or LiNbO₃, wherein the thickness of the piezoelectric layer is preferably between 0.5 μm and 5 μm.

### BACKGROUND OF THE INVENTION

1. Field of the Invention

The present invention relates to a surface acoustic wave device and, more particularly, to a high frequency surface acoustic wave device, which can modulate its central frequency by changing the thickness of the nanocrystalline diamond layer thereof.

2. Description of Related Art

Currently, due to the development of the material technology, the high frequency surface acoustic wave device can be used as a filter. The high frequency surface acoustic wave device is widely used in the mobile communication technology. Besides, since the high frequency surface acoustic wave device has many benefit such as low loss, high attenuation, and limited size and weight, the applications of the high frequency surface acoustic wave device are widened. However, for the most popular substrate, i.e. the LiNbO₃ substrate, if a central frequency of the high frequency surface acoustic wave device having the LiNbO₃ substrate must achieve 1800 MHz, the linewidth of the input transformation unit and the output transformation unit of the high frequency surface acoustic wave device needs to be as narrow as 0.5 μm, which is difficult to manufacture by a conventional contact-type aligner.

On the other hand, for widening the application field of the high frequency surface acoustic wave device, the industry has already proposed some solutions to modulate the central frequency of the high frequency surface acoustic wave device.

With reference to FIG. 1A and FIG. 1B, the conventional high frequency surface acoustic wave device comprises: a piezoelectric substrate 11, an input transformation unit 12, and an output transformation unit 13, wherein the input transformation unit 12 and the output transformation unit 13 are formed in pairs on the surface of the piezoelectric substrate 11. The piezoelectric substrate 11 is made of quartz, LiNbO₃ or LiTaO₃. However, once the linewidth of the input transformation unit 12 and the output transformation unit 13 is confirmed, the central frequency of the conventional high frequency surface acoustic wave device is extremely difficult to modulate. In other words, the only way to modulate the central frequency of the conventional high frequency surface acoustic wave device is to change the linewidth of the input transformation unit 12 and the output transformation unit 13. Moreover, if the linewidth of the input transformation unit 12 and the output transformation unit 13 is going to be changed, a new photomask having the new patterns with the new linewidth must be manufactured. As a result, extra cost and time related to the new photomask are incurred.

Therefore, a high frequency surface acoustic wave device, which can modulate its central frequency by changing the thickness of the nanocrystalline diamond layer thereof is required. On the other hand, although the modulation of the central frequency of a high frequency surface acoustic wave device having the layer-structure made of the piezoelectric material can be achieved by changing the thickness of the piezoelectric layer, the huge raising of the central frequency thereof can only be achieved by changing the thickness of the piezoelectric layer and using the material having high acoustic velocity in the high frequency surface acoustic wave device, such as the nanocrystalline diamond layer.

### SUMMARY OF THE INVENTION

The first object of the present invention is to provide a high frequency surface acoustic wave device, which can module its central frequency by changing the thickness of the nanocrystalline diamond layer thereof.

The second object of the present invention is to provide a high frequency surface acoustic wave device, which can simplify the process to modulate the central frequency thereof and enlarge its application flexibility.

To achieve the object, the high frequency surface acoustic wave device of the present invention comprises: a silicon substrate; a nanocrystalline diamond layer located above the silicon substrate; a piezoelectric layer formed on the surface of the nanocrystalline diamond layer; an input transformation unit; and an output transformation unit; wherein the input transformation unit and the output transformation unit are formed in pairs on the surface of the piezoelectric layer.

On the other hand, the high frequency surface acoustic wave device of the present invention can also comprise: a silicon substrate; a nanocrystalline diamond layer located above the silicon substrate; a piezoelectric layer formed on the surface of the nanocrystalline diamond layer; an input transformation unit; and an output transformation unit; wherein the input transformation unit and the output transformation unit are formed in pairs on the surface of the nanocrystalline diamond layer, and the piezoelectric layer covers parts of the surface of the nanocrystalline diamond layer located between the input transformation unit and the output transformation unit.

Therefore, the high frequency surface acoustic wave device of the present invention can modulate its central frequency by changing the thickness of the nanocrystalline diamond layer thereof, without the need to change the linewidth of the input transformation unit and the output transformation unit thereof. As a result, the process to modulate the central frequency of the high frequency surface acoustic wave device of the present invention is simplified into merely controlling the deposition time of the nanocrystalline diamond layer thereof. Hence, the application flexibility of the high frequency surface acoustic wave device of the present invention is greater than that of a conventional high frequency surface acoustic wave device.

The substrate of the high frequency surface acoustic wave device of the present invention can be made of any kind of material, but the substrate thereof is preferably a silicon (100) die. The nanocrystalline diamond layer of the high frequency surface acoustic wave device of the present invention can have any thickness, but the thickness of the nanocrystalline diamond layer thereof is preferably between 0.5 μm and 20 μm. The piezoelectric layer of the high frequency surface acoustic wave device of the present invention can be made of any kind of material, but the piezoelectric layer thereof is preferably made of ZnO, AlN, or LiNbO₃. The piezoelectric layer of the high frequency surface acoustic wave device of the present invention can be formed on the surface of the nanocrystalline diamond layer by any kind of manufacturing process, but the piezoelectric layer thereof is preferably formed on the surface of the nanocrystalline diamond layer by a radio frequency magnetron sputtering process, an electron-beam evaporation process, a chemical vapor deposition process, an excimer laser deposition process, a sol-gel process, or a physical vapor deposition process. The input transformation unit and the output transformation unit of the high frequency surface acoustic wave device of the present invention can have any kind of linewidth, but the linewidth thereof is preferably between 0.5 μm and 5 μm. The input transformation unit and the output transformation unit of the high frequency surface acoustic wave device of the present invention can be made of any kind of material, but they are preferably made of aluminum. The thickness of the input transformation unit and the output transformation unit of the high frequency surface acoustic wave device of the present invention is preferably between 50 nm to 200 nm.

Other objects, advantages, and novel features of the invention will become more apparent from the following detailed description when taken in conjunction with the accompanying drawings.

### BRIEF DESCRIPTION OF THE DRAWINGS

FIG. 1A is a perspective view of a conventional high frequency surface acoustic wave device.

FIG. 1B is a cross-sectional view taken along the AA′ plane of the FIG. 1A.

FIG. 2A is a perspective view of the high frequency surface acoustic wave device according to the first embodiment of the present invention.

FIG. 2B is a cross-sectional view taken along the BB′ plane of the FIG. 2A.

FIG. 2C shows the frequency response of the high frequency surface acoustic wave device according to the first embodiment of the present, invention.

FIG. 2D shows the relation between the phase velocity of the surface acoustic wave and the thickness of the nanocrystalline diamond layer of the high frequency surface acoustic wave device according to the first embodiment of the present invention.

FIG. 3A is a perspective view of the high frequency surface acoustic wave device according to the second embodiment of the present invention.

FIG. 3B is a cross-sectional view taken along the CC′ plane of the FIG. 3A.

FIG. 3C shows the frequency response of the high frequency surface acoustic wave device according to the second embodiment of the present invention.

FIG. 3D shows the relation between the phase velocity of the surface acoustic wave and the thickness of the nanocrystalline diamond layer of the high frequency surface acoustic wave device according to the second embodiment of the present invention.

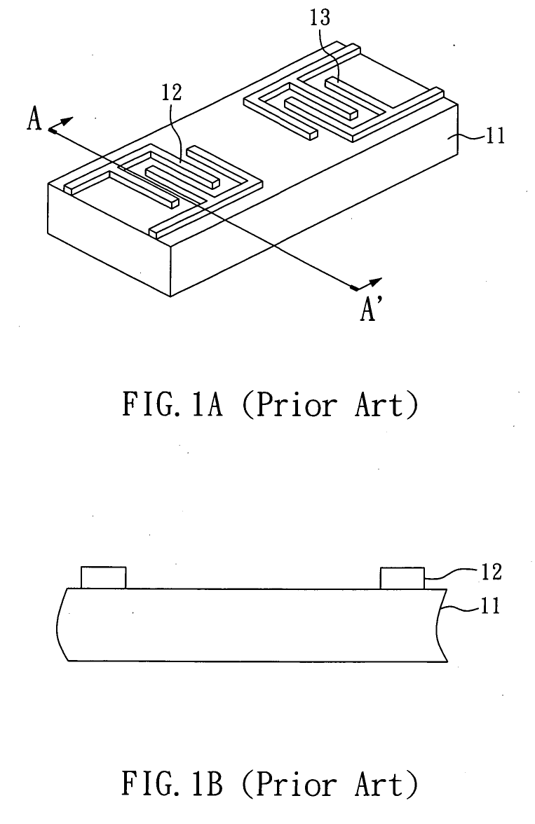

### DETAILED DESCRIPTION OF THE PREFERRED EMBODIMENT

### Embodiment 1

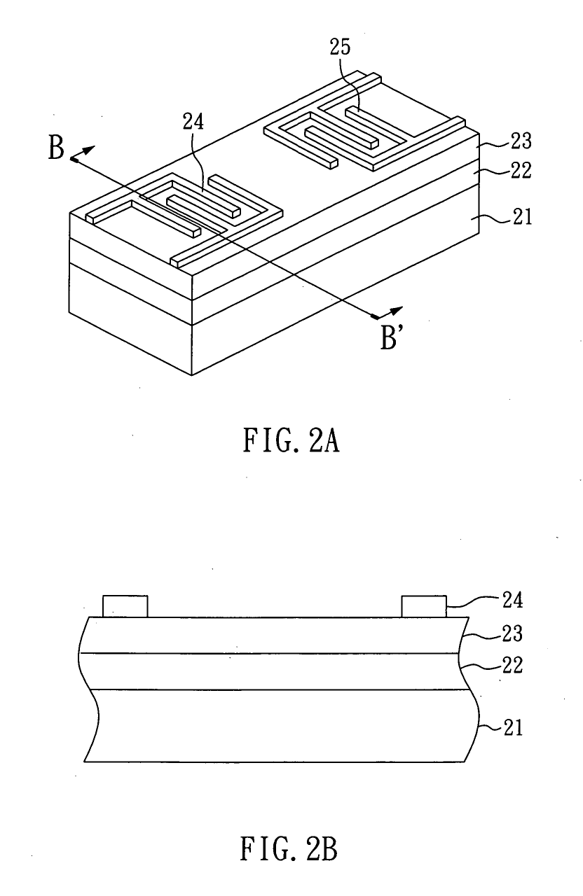

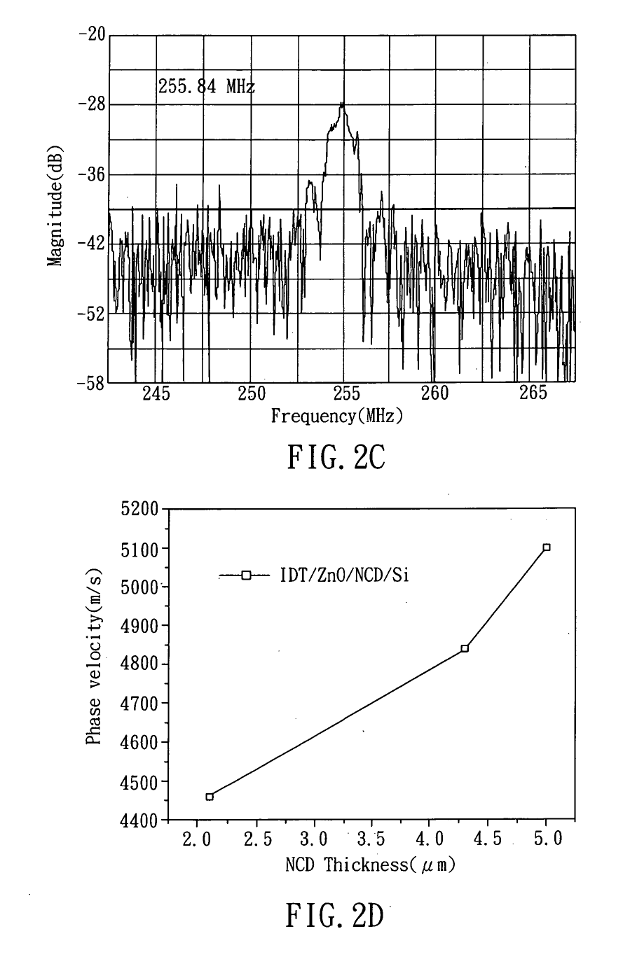

With reference to FIG. 2A and FIG. 2B, wherein FIG. 2A is a perspective view of the high frequency surface acoustic wave device according to the first embodiment of the present invention, FIG. 2B is a cross-sectional view taken along the BB′ plane of the FIG. 2A.

The high frequency surface acoustic wave device according to the first embodiment of the present invention comprises: a silicon substrate 21, a nanocrystalline diamond layer 22, a piezoelectric layer 23, an input transformation unit 24, and an output transformation unit 25, wherein the input transformation unit 24 and the output transformation unit 25 are formed in pairs on the surface of the piezoelectric layer 23. In the present embodiment, the piezoelectric layer 23 made of ZnO is formed on the surface of the nanocrystalline diamond layer 22 by a radio frequency magnetron sputtering process. The deposition parameters of the radio frequency magnetron sputtering process are listed in Table 1 below:

TABLE 1

| | ZnO target doped with |
|---|---|
| Material of the target | 0.5-1 wt. % Li₂O |
| Distance between the target and the substrate | 43 mm |
| Substrate temperature | 380° C. |
| Flow ratio of the sputtering gases | Ar/O₂ = 1 |
| RF power | 178 W |
| Deposition time | 30 minutes |
| Deposition pressure | 10 mtorr |
| Thickness of the deposition | 1.2 μm |

Then, a photoresist layer is dispensed on the surface of the piezoelectric layer 23. By executing a photolithography process, a pattern of the interdigital electrodes is formed. Later, an aluminum layer having the thickness about 100 nm is formed on the pattern by an evaporation process.

The unwanted part of the aluminum layer and the photoresist layer are removed by a lift-off process. The input transformation unit 24 and the output transformation unit 25 are formed on the surface of the piezoelectric layer 23. After the above process is completed, the thickness of the nanocrystalline diamond layer 22 is about 5 μm. The thickness of the piezoelectric layer 23, which is made of ZnO, is about 1.2 μm. The input transformation unit 24 and the output transformation unit 25 are made of aluminum, and their linewidth is about 5 μm.

The frequency response of the high frequency surface acoustic wave device according to the first embodiment of the present invention is shown in FIG. 2C. As shown in the figure, the central frequency of the high frequency surface acoustic wave device is about 255.84 MHz.

On the other hand, two high frequency surface acoustic wave devices are also formed by the same manufacturing process described above. In these two high frequency surface acoustic wave devices, the thickness of the nanocrystalline diamond layer are different with each other, they are 2.1 μm and 4.3 μm, respectively. Besides, the size and material of other elements (such as the silicon substrate, the piezoelectric layer, the input transformation unit, and the output transformation unit) of these two high frequency surface acoustic wave devices are the same as the corresponding element of the high frequency surface acoustic wave device according to the first embodiment of the present invention.

The phase velocities of the surface acoustic wave of these two high frequency surface acoustic wave devices and that of the surface acoustic wave of the high frequency surface acoustic wave device according to the first embodiment of the present invention are measured, and the measurement results are shown in FIG. 2D. As shown in the figure, the phase velocity of the surface acoustic wave of the high frequency surface acoustic wave device according to the first embodiment of the present invention can be modulated by changing the thickness of the nanocrystalline diamond layer thereof, while the size and material of the other elements (such as the silicon substrate, the piezoelectric layer, the input transformation unit, and the output transformation unit) thereof remain the same.

### Embodiment 2

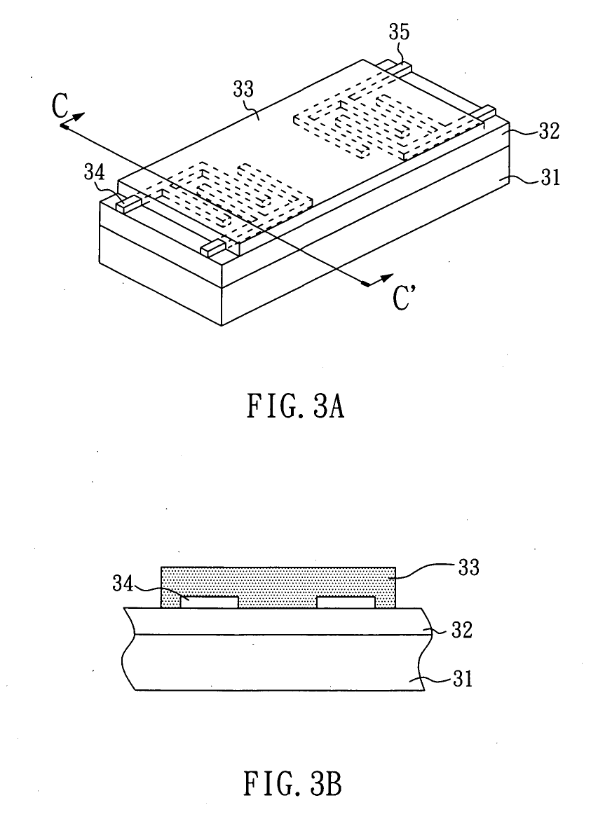

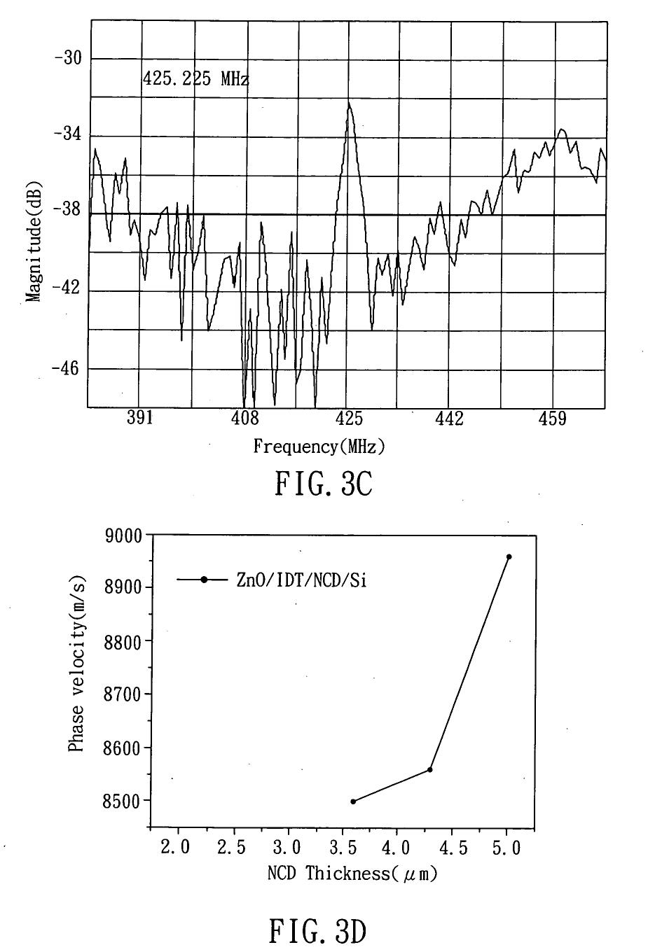

With reference to FIG. 3A and FIG. 3B, FIG. 3A is a perspective view of the high frequency surface acoustic wave device according to the second embodiment of the present invention, FIG. 3B is a cross-sectional view taken along the CC′ plane of the FIG. 3A.

The high frequency surface acoustic wave device according to the second embodiment of the present invention comprises: a silicon substrate 31, a nanocrystalline diamond layer 32, a piezoelectric layer 33, an input transformation unit 34, and an output transformation unit 35, wherein the input transformation unit 34 and the output transformation unit 35 are formed in pairs on the surface of the nanocrystalline diamond layer 32, and the piezoelectric layer 33 covers parts of the surface of the nanocrystalline diamond layer 32 located between the input transformation unit 34 and the output transformation unit 35.

In the present embodiment, a photoresist layer is dispensed on the surface of the nanocrystalline diamond layer 32. By executing a photolithography process, a pattern of the interdigital electrodes is formed. Later, an aluminum layer having the thickness about 100 nm is formed on the pattern by an evaporation process. The unwanted part of the aluminum layer and the photoresist layer are removed by a lift-off process. The input transformation unit 34 and the output transformation unit 35 are formed on the surface of the nanocrystalline diamond layer 32. Then, the piezoelectric layer 33 made of ZnO is formed on the surface of the nanocrystalline diamond layer 32 by a radio frequency magnetron sputtering process, wherein the piezoelectric layer 33 covers parts of the surface of the nanocrystalline diamond layer 32 located between the input transformation unit 34 and the output transformation unit 35. The deposition parameters of the radio frequency magnetron sputtering process are listed in Table 1 above.

After the above process is completed, the thickness of the nanocrystalline diamond layer 32 is about 3.6 μm. The thickness of the piezoelectric layer 33, which is made of ZnO, is about 1.2 μm. The input transformation unit 34 and the output transformation unit 35 are made of aluminum, and their linewidth is about 5 μm.

The frequency response of the high frequency surface acoustic wave device according to the second embodiment of the present invention is shown in FIG. 3C. As shown in the figure, the central frequency of the high frequency surface acoustic wave device is about 425.225 MHz.

On the other hand, two high frequency surface acoustic wave devices are also formed by the same manufacturing process described above. In these two high frequency surface acoustic wave devices, the thickness of the nanocrystalline diamond layer are different with each other, they are 4.3 μm and 5.0 μm, respectively. Besides, the size and material of other elements (such as the silicon substrate, the piezoelectric layer, the input transformation unit, and the output transformation unit) of these two high frequency surface acoustic wave devices are the same as the corresponding element of the high frequency surface acoustic wave device according to the second embodiment of the present invention.

The phase velocities of the surface acoustic wave of these two high frequency surface acoustic wave devices and that of the surface acoustic wave of the high frequency surface acoustic wave device according to the second embodiment of the present invention are measured, and the measurement results are shown in FIG. 3D. As shown in the figure, the phase velocity of the surface acoustic wave of the high frequency surface acoustic wave device according to the second embodiment of the present invention can be modulated by changing the thickness of the nanocrystalline diamond layer. Moreover, the size and material of the other elements (such as the silicon substrate, while the piezoelectric layer, the input transformation unit, and the output transformation unit) thereof remain the same.

As described above, the high frequency surface acoustic wave device of the present invention can modulate its central frequency by changing the thickness of the nanocrystalline diamond layer thereof, without the need to change the linewidth of the input transformation unit and the output transformation unit thereof. As a result, the process to modulate the central frequency of the high frequency surface acoustic wave device of the present invention is simplified into merely controlling the deposition time of the nanocrystalline diamond layer thereof. Hence, the application flexibility of the high frequency surface acoustic wave device of the present invention is greater than that of a conventional high frequency surface acoustic wave device.

Although the present invention has been explained in relation to its preferred embodiment, it is to be understood that many other possible modifications and variations can be made without departing from the spirit and scope of the invention as hereinafter claimed.

What is claimed is:

1. A high frequency surface acoustic wave device comprising:
a silicon substrate;
a nanocrystalline diamond layer located above the silicon substrate;
a piezoelectric layer formed on the surface of the nanocrystalline diamond layer;
an input transformation unit; and
an output transformation unit;
wherein the input transformation unit and the output transformation unit are formed in pairs on the surface of the piezoelectric layer.

2. The high frequency surface acoustic wave device as claimed in claim 1, wherein the silicon substrate is a silicon (100) die.

3. The high frequency surface acoustic wave device as claimed in claim 1, wherein the thickness of the nanocrystalline diamond layer is between 0.5 μm and 20 μm.

4. The high frequency surface acoustic wave device as claimed in claim 1, wherein the piezoelectric layer is formed on the surface of the nanocrystalline diamond layer by a radio frequency magnetron sputtering process.

5. The high frequency surface acoustic wave device as claimed in claim 1, wherein the piezoelectric layer is made of ZnO, AlN, or LiNbO₃.

6. The high frequency surface acoustic wave device as claimed in claim 1, wherein the linewidth of the input transformation unit and the output transformation unit is between 0.5 μm and 5 μm.

7. The high frequency surface acoustic wave device as claimed in claim 1, wherein the input transformation unit and the output transformation unit are an interdigital electrode, respectively.

8. The high frequency surface acoustic wave device as claimed in claim 1, wherein the input transformation unit and the output transformation unit are made of aluminum.

9. A high frequency surface acoustic wave device comprising:
a silicon substrate;
a nanocrystalline diamond layer located above the silicon substrate;
a piezoelectric layer formed on the surface of the nanocrystalline diamond layer;
an input transformation unit; and
an output transformation unit;
wherein the input transformation unit and the output transformation unit are formed in pairs on the surface of the nanocrystalline diamond layer, and the piezoelectric layer covers parts of the surface of the nanocrystalline diamond layer located between the input transformation unit and the output transformation unit.

10. The high frequency surface acoustic wave device as claimed in claim 9, wherein the silicon substrate is a silicon (100) die.

11. The high frequency surface acoustic wave device as claimed in claim 9, wherein the thickness of the nanocrystalline diamond layer is between 0.5 μm and 20 μm.

12. The high frequency surface acoustic wave device as claimed in claim 9, wherein the piezoelectric layer is formed on the surface of the nanocrystalline diamond layer by a radio frequency magnetron sputtering process.

13. The high frequency surface acoustic wave device as claimed in claim 9, wherein the piezoelectric layer is made of ZnO, AlN, or LiNbO₃.

14. The high frequency surface acoustic wave device as claimed in claim 9, wherein the linewidth of the input transformation unit and the output transformation unit is between 0.5 μm and 5 μm.

15. The high frequency surface acoustic wave device as claimed in claim 9, wherein the input transformation unit and the output transformation unit are an interdigital electrode, respectively.

16. The high frequency surface acoustic wave device as claimed in claim 9, wherein the input transformation unit and the output transformation unit are made of aluminum.
